(19) United States
(12) Patent Application Publication
(10) Pub. No.: US 2022/0336536 A1
(43) Pub. Date: Oct. 20, 2022

(54) DISPLAY DEVICE

(71) Applicant: Samsung Display Co., Ltd., Yongin-Si (KR)

(72) Inventors: JEONGHYUN KWON, Asan-si (KR); JINBO SHIM, Yongin-si (KR); JAENEUNG KIM, Seoul (KR)

(21) Appl. No.: 17/643,845

(22) Filed: Dec. 13, 2021

(30) Foreign Application Priority Data
Apr. 19, 2021 (KR) 10-2021-0050717

(51) Int. Cl. H01L 27/32; G06F 3/044; H01L 51/52

(52) U.S. Cl. CPC H01L 27/323; G06F 3/0446; H01L 51/5253; H01L 27/322; G06F 2203/04111

(57) ABSTRACT

A display device is disclosed that includes a display panel including a plurality of pixel regions, and an input-sensing unit including an inorganic material-containing optical layer disposed on the display panel, and a plurality of metal patterns disposed on the optical layer and respectively corresponding to the plurality of pixel regions. The plurality of pixel regions include a first pixel region and a second pixel region, and the plurality of metal patterns include a first metal pattern overlapping the first pixel region and transmitting first light, and a second metal pattern overlapping the second pixel region and transmitting second light having a wavelength different from that of the first light. The display device has improved sensing sensitivity, and a reduced thickness in total.

### CROSS-REFERENCE TO RELATED APPLICATIONS

This U.S. non-provisional patent application claims priority under 35 U.S.C. § 119 of Korean Patent Application No. 10-2021-0050717, filed on Apr. 19, 2021, the entire contents of which are hereby incorporated by reference.

### BACKGROUND

The present disclosure relates to a display device, and more particularly, to a display device including an input-sensing unit with improved sensing sensitivity.

Electronic devices such as smart phones, tablet PCs, notebook computers, and smart televisions are being developed. Such electronic devices are provided with a display device for providing information. Electronic devices further include various electronic modules besides a display device.

Display devices include an input-sensing panel as an input apparatus. The input-sensing panel may be disposed on a display panel that displays images.

### SUMMARY

An embodiment of the inventive concept provides a display device including: a display panel including a plurality of pixel regions; an input-sensing unit including an inorganic material-containing optical layer disposed on the display panel, and a plurality of metal patterns disposed on the optical layer and respectively corresponding to the plurality of pixel regions. The plurality of pixel regions include a first pixel region and a second pixel region, and the plurality of metal patterns include a first metal pattern overlapping the first pixel region and transmitting first light, and a second metal pattern overlapping the second pixel region and transmitting second light having a wavelength different from that of the first light.

In an embodiment, the first metal pattern includes a plurality of first holes, and the second metal patter includes a plurality of second holes having a planar arrangement different from that of the plurality of first holes.

In an embodiment, the input-sensing unit further includes a first oxide layer disposed on the first metal pattern; and a second oxide layer disposed on the second metal pattern.

In an embodiment, the first oxide layer and the second oxide layer may each include a transparent conductive oxide.

In an embodiment, the first oxide layer is disposed filling the plurality of first holes and the second oxide layer is disposed filling the plurality of second holes.

In an embodiment, the plurality of first holes may have a first width, and the plurality of second holes may have a second width different from the first width.

In an embodiment, the plurality of first holes may be arranged with a first period, and the plurality of second holes may be arranged with a second period different from the first period.

In an embodiment, the plurality of first holes may penetrate through the first metal pattern, and the plurality of second holes may penetrate through the second metal pattern.

In an embodiment, the optical layer may include a plurality of inorganic films having refractive indices different from each other.

In an embodiment, the optical layer may include: at least one first inorganic film having a first refractive index; and at least one second inorganic film having a second refractive index different from the first refractive index, the at least one first inorganic film and the at least one second inorganic film being alternately stacked.

In an embodiment, the input-sensing unit may further include a light-blocking pattern disposed between the plurality of metal patterns.

In an embodiment, the display panel may further include an encapsulation layer covering the plurality of pixel regions, and the input-sensing unit is directly disposed on the encapsulation layer.

In an embodiment, the input sensing unit includes first sensing areas and second sensing areas. Each of the first sensing areas include the first pixel region and the second pixel region. The first sensing areas are electrically connected and extend in a first direction. Each of the second sensing areas include the first pixel region and the second pixel region. The second sensing areas are electrically connected and extend in a second direction different from the first direction.

In an embodiment of the inventive concept, a display device includes a display panel including a plurality of first pixel regions generating first light, and a plurality of second pixel regions generating second light having a wavelength different from that of the first light; and an input-sensing unit disposed on the display panel, and including a first color filter overlapping the plurality of first pixel regions and a second color filter overlapping the plurality of second pixel regions The first color filter includes a first metal pattern that includes a plurality of first holes A first oxide layer fills the plurality of first holes. The second color filter includes a second metal pattern that includes a plurality of second holes having a planar arrangement different from that of the plurality of first holes. A second oxide layer fills the plurality of second holes.

In an embodiment, the input-sensing unit may further include an optical layer disposed between the display panel and the first and second color filters, and the optical layer has a multi-layered structure in which a plurality of inorganic films having different refractive indices are alternately stacked.

In an embodiment, the plurality of first holes may be arranged with a first period, and the plurality of second holes may be arranged with a second period different from the first period.

In an embodiment, the plurality of first holes may penetrate through the first metal pattern, and the plurality of second holes may penetrate through the second metal pattern.

In an embodiment, the first oxide layer and the second oxide layer may each include a transparent conductive oxide.

In an embodiment, the first light may be red light, and the second light may be green light.

In an embodiment, the display panel further may include a plurality of third pixel regions generating third light having a wavelength different from those of the first light and the second light, the input-sensing unit may further include a third color filter disposed on the display panel, and overlapping the plurality of third pixel regions. The third color filter may include a third metal pattern that includes a plurality of third holes. A third oxide layer fills the plurality of third holes and disposed on the third metal pattern.

In an embodiment, the plurality of first holes may each have a first width, the plurality of second holes may each have a second width different from the first width, and the plurality of third holes may each have a third width different from the first width and the second width, the first width being about 540 nm to about 640 nm, the second width being about 450 nm to about 550 nm, and the third width being about 350 nm to about 450 nm.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a perspective view of a display device according to an embodiment of the inventive concept;

FIG. 1B is an exploded perspective view of a display device according to an embodiment of the inventive concept;

FIG. 1C is a cross-sectional view of a display device according to an embodiment of the inventive concept;

FIG. 2 is a plan view of a display panel according to an embodiment of the inventive concept;

FIG. 3 is a plan view of an input-sensing unit according to an embodiment of the inventive concept;

FIG. 4 is an enlarged plan view illustrating an input-sensing unit according to an embodiment of the inventive concept and corresponding to region BB illustrated in FIG. 3;

FIG. 5A is an enlarged plan view illustrating a display panel according to an embodiment of the inventive concept and corresponding to region FFa illustrated in FIG. 2;

FIG. 5B is an enlarged plan view illustrating an input-sensing unit according to an embodiment of the inventive concept and corresponding to region FFb illustrated in FIG. 3;

FIG. 6A is a cross-sectional view illustrating a display module according to an embodiment of the inventive concept and taken along line II-II′ illustrated in FIG. 4;

FIG. 6B is a cross-sectional view in which part GG illustrated in FIG. 6A is enlarged;

FIG. 7A is a plan view magnifying region CC of FIG. 4;

FIG. 7B is a cross-sectional view of a display module according to an embodiment of the inventive concept and taken along cutting line III-III′ illustrated in FIG. 7A; and

FIGS. 8A, 8B, and 8C are enlarged plan views of a portion of an input-sensing unit according to another embodiment of the inventive concept.

### DETAILED DESCRIPTION

An embodiment of the inventive concept provides a display device including an input-sensing unit in which a color filter and an input sensor are integrated to improve a sensing sensitivity and have a reduced thickness in total.

In this specification, when a component (or region, layer, portion, etc.) is referred to as “on”, “connected”, or “coupled” to another component, it means that it is placed/connected/coupled directly on the other component or a third component can be disposed between them.

The same reference numerals refer to the same elements. In addition, in the drawings, thicknesses, ratios, and dimensions of components are exaggerated for effective description of technical content.

As used herein, the word “or” means logical “or” so, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

Terms such as first and second may be used to describe various components, but the components should not be limited by the terms. These terms are only used for the purpose of distinguishing one component from other components. For example, without departing from the scope of the present invention, a first component may be referred to as a second component, and similarly, a second component may be referred to as a first component. Singular expressions include plural expressions unless the context clearly indicates otherwise.

In addition, terms such as “below”, “lower”, “above”, and “upper” are used to describe the relationship between components shown in the drawings. The terms are relative concepts and are described based on the directions indicated in the drawings.

Terms such as “comprise,” “include,” and “have” are intended to designate the presence of a feature, number, step, action, component, part, or combination thereof described in the specification, and it should be understood that it does not preclude the possibility of presence or addition of one or more other features, numbers, steps, operations, components, parts, or combinations thereof.

In the present application, “directly in contact” may mean that there is no layer, film, region, plate, etc. added between a portion such as a layer, film, region, or plate and another portion. For example, “direct contact” may mean placing two layers or two members without using an additional member such as an adhesive member therebetween.

Unless otherwise defined, all terms (including technical and scientific terms) used in this specification have the same meaning as commonly understood by one of ordinary skill in the art to which this invention belongs. In addition, terms such as terms defined in commonly used dictionaries should be interpreted as having a meaning consistent with the meaning having in the context of the related technology, and should not be interpreted as too ideal or too formal unless explicitly defined here.

Hereinafter, embodiments of the inventive concept will be described with reference to the accompanying drawings.

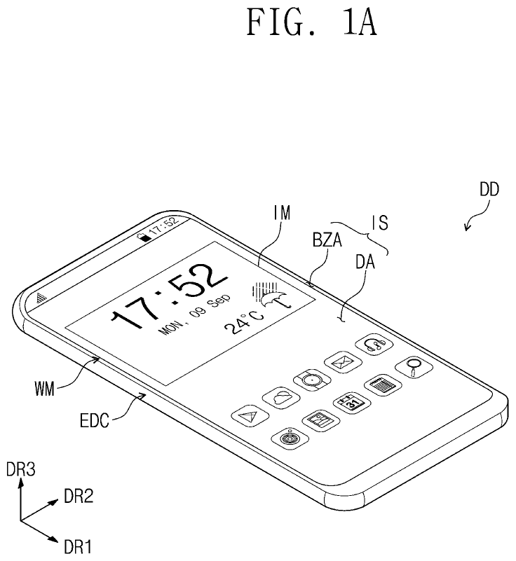

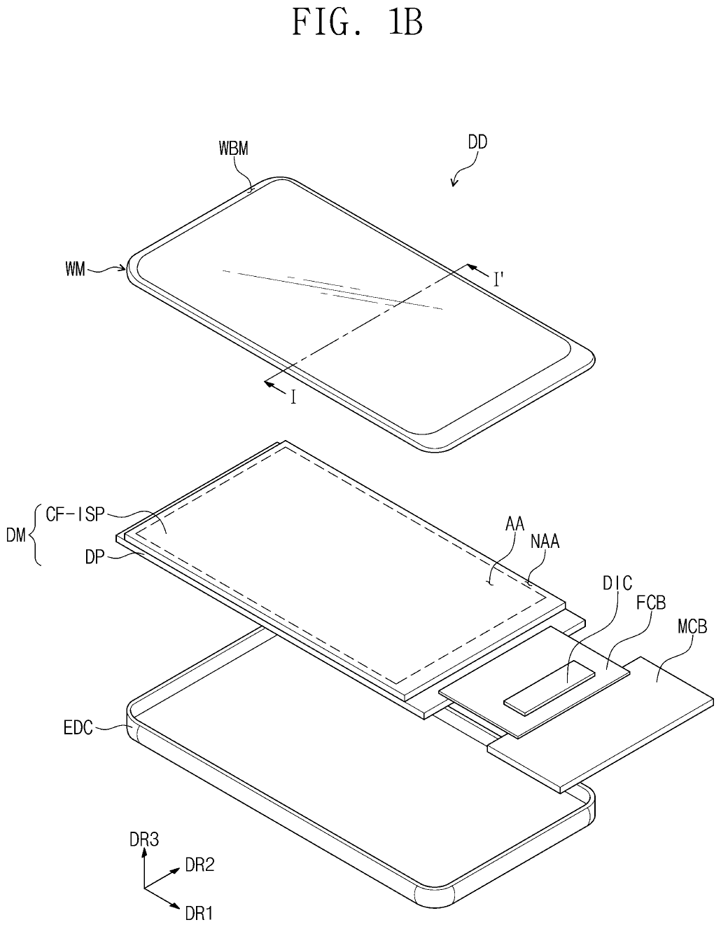

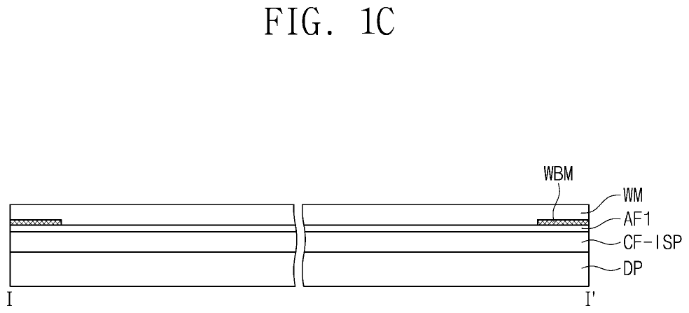

FIG. 1A is a perspective view of a display device according to an embodiment of the inventive concept. FIG. 1B is an exploded perspective view of a display device according to an embodiment of the inventive concept. FIG. 1C is a cross-sectional view of a display device according to an embodiment of the inventive concept. FIG. 1C is a cross-sectional view taken along cutting line I-I′ illustrated in FIG. 1B.

Referring to FIGS. 1A to 1C, a display device DD may be activated in response to an electrical signal. The display device DD may include various embodiments. For example, the display device DD may be applied to electronic devices such as smart watches, tablet PCs, notebook computers, computers, and smart televisions.

The display device DD may display images IM in a third direction DR3 on a display surface IS parallel to each of a first direction DR1 and a second direction DR2. The display surface IS displaying images IM may correspond to the front surface of the display device DD. The images IM may include still images as well as dynamic images.

In this embodiment, the front surface (or upper surface) and the rear surface (or lower surface) of each member are defined based on a direction in which images IM are displayed. The front surface and the rear surface may oppose each other in the third direction DR3, and the normal direction of each of the front surface and the rear surface may be parallel to the third direction DR3.

The separation distance between the front surface and the rear surface in the third direction DR3 may correspond to the thickness of the display device DD in the third direction DR3. Meanwhile, directions indicated by the first to third directions DR1, DR2, and DR3 are relative concepts, and may be changed to other directions.

The display device DD may sense an external input applied from the outside. The external input may include various forms of inputs provided from the outside of the display device DD. The external input is an input applied from the outside, and may be provided in various forms.

For example, the external input may include not only touch by a part of a body such as a user's hand, but also an external input (for example, hovering) applied in proximity to the display device DD, or adjacent to the display device DD at a predetermined distance. In addition, the external input may have various forms such as force, pressure, temperature, and light.

The front surface of the display device DD may be divided into a display region DA and a bezel region BZA. The display region DA may be a region in which images IM are displayed. A user visually recognizes images IM through the display region DA. In this embodiment, the display region DA is illustrated as a rectangular shape with rounded vertices, but this is exemplarily illustrated. The display region DA may have various shape, and is not limited to any one embodiment.

The bezel region BZA is adjacent to the display region DA. The bezel region BZA may have a predetermined color. The bezel region BZA may surround the display region DA. Accordingly, the shape of the display region DA may be substantially defined by the bezel region BZA, but this is exemplarily illustrated. Thus, the bezel region BZA may be disposed adjacent to a side of the display region DA, and may also be omitted. The display device DD according to an embodiment of the inventive concept may include various embodiments, and is not limited to any one embodiment.

As illustrated in FIGS. 1B and 1C, the display device DD may include a window WM, an outer case EDC, and a display module DM. The display module DM may include a display panel DP and an input-sensing unit CF-ISP.

The window WM may be composed of a transparent material which may project images, for example, glass, sapphire, plastic, etc. The window WM is illustrated as a single layer, but an embodiment of the inventive concept is not limited thereto, and the window WM may be multiple layers. Meanwhile, although not shown, the bezel region BZA of the aforementioned display device DD may be provided substantially as a region in which a material having a predetermined color is printed onto one region of the window WM. In an embodiment, the window WM may include a bezel pattern WBM for defining the bezel region BZA. The bezel pattern WBM is a colored organic film, and may be formed, for example, through a coating process.

The display panel DP according to an embodiment of the inventive concept may be a light-emitting display panel, but an embodiment of the inventive concept is not specially limited thereto. For example, the display panel DP may be an organic light-emitting display panel, or a quantum dot light-emitting display panel. A light-emitting layer of the organic light-emitting display panel may include an organic light-emitting material. A light-emitting layer of the quantum dot light-emitting display panel may include quantum dots, and quantum rods, etc. Hereinafter, the display panel DP will be described as an organic light-emitting display panel.

The input-sensing unit CF-ISP may be directly disposed on the display panel DP. According to an embodiment of the inventive concept, the input-sensing unit CF-ISP may be formed on the display panel DP through a continuous process. That is, when the input-sensing unit CF-ISP is directly disposed on the display panel DP, an adhesive film is not disposed between the input-sensing unit CF-ISP and the display panel DP. However, an embodiment of the inventive concept is not limited thereto, and an adhesive film may be disposed between the input-sensing unit CF-ISP and the display panel DP. In this case, the input-sensing unit CF-ISP and the display panel DP are not manufactured through a continuous process, but are manufactured through separate processes, and then may be fixed to the upper surface of the display panel DP by an adhesive film.

The display panel DP generates images, and the input-sensing unit CF-ISP acquires coordinate information on an external input (for example, a touching event).

The input-sensing unit CF-ISP may include a base layer, and a plurality of color filters disposed on the base layer. The plurality of color filters may fulfil anti-reflection function that minimizes reflection of light provided from the outside of the display device DD. For example, the plurality of color filters may block a part of external light. The plurality of color filters may be disposed on the display panel DP, and minimize decrease in luminescence while reducing reflection of external light.

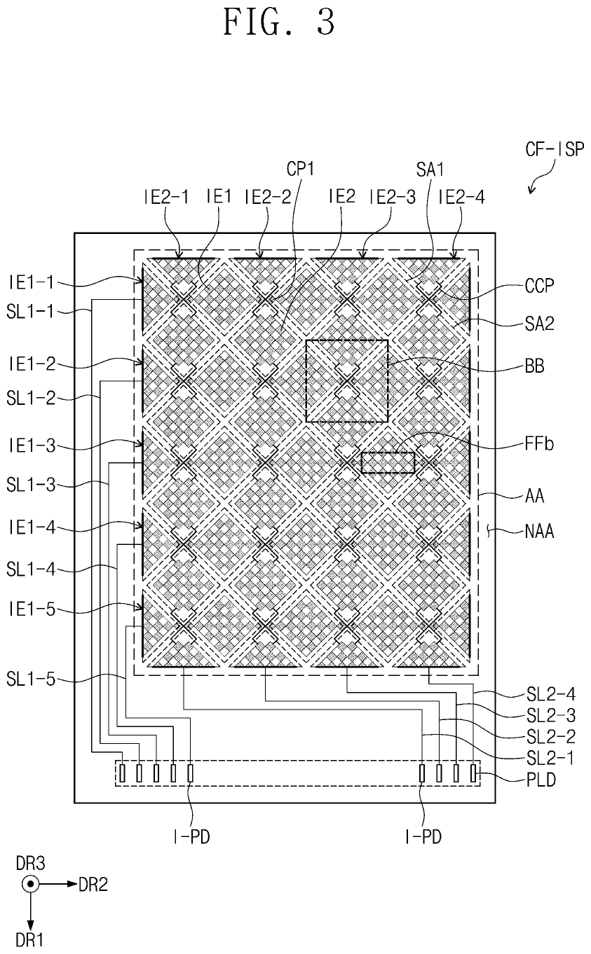

The plurality of color filters may include a plurality of conductive color filters. The plurality of color filters may perform an input-sensing function for sensing an external input, in addition to the anti-reflection function. The arrangement structure of the plurality of color filters will be described later in detail with reference to FIGS. 3 to 6B.

The input-sensing unit CF-ISP may be disposed between the display panel DP and the window WM. The input-sensing unit CF-ISP and the window WM may be bonded to each other via an adhesive film. A first adhesive film AF1 may be disposed between the input-sensing unit CF-ISP and the window WM. In an embodiment, an optically clear adhesive (OCA) film may be included as a first adhesive film AF1. However, the first adhesive film AF1 is not limited thereto, and may include a typical bonding agent or adhesive. For example, the first adhesive film AF1 may include an optically clear resin (OCR) or a pressure sensitive adhesive (PSA) film.

The display module DM may display images in response to an electrical signal, and may transmit/receive information pertaining to an external input. An active region AA and a peripheral region NAA may be defined in the display module DM. The active region AA may be defined as a region in which images provided by the display module DM are projected.

The peripheral region NAA is adjacent to the active region AA. For example, the peripheral region NAA may surround the active region AA. However, this is exemplarily illustrated, and the peripheral region NAA may be defined in various shapes and is not limited to any one embodiment. According to an embodiment, the active region AA of the display module DM may correspond to at least a portion of the display region DA.

The display module DM may further include a main circuit board MCB, a flexible circuit board FCB, and a driving chip DIC.

The main circuit board MCB may be connected to the flexible circuit board FCB, and may be electrically connected to the display panel DP. The main circuit board MCB may include a plurality of driving elements. The plurality of driving elements may include a circuit portion for driving the display panel DP.

The flexible circuit board FCB may be connected to the display panel DP, and electrically connect the display panel DP and the main circuit board MCB. The driving chip DIC may be mounted on the flexible circuit board FCB.

The driving chip DIC may include driving elements for driving pixels of the display panel DP, for example a data driving circuit. The flexible circuit board FCB according to an embodiment of the inventive concept is illustrated as one, but an embodiment of the inventive concept is not limited thereto. The flexible circuit board FCB may be provided in plurality and may be connected to the display panel DP.

FIG. 1B illustrates a structure in which the driving chip DIC is mounted on the flexible circuit board FCB, but an embodiment of the inventive concept is not limited thereto. For example, the driving chip DIC may be directly mounted on the display panel DP. In this case, a portion of the display panel DP on which the driving chip DIC is mounted may be bent, and disposed on the rear surface of the display module DM.

The input sensing unit CF-ISP may be electrically connected to the main circuit board MCB through the flexible circuit board FCB. However, an embodiment of the inventive concept is not limited thereto. That is, the display module DM may further include a separate flexible circuit board for electrically connecting the input sensing unit CF-ISP with the main circuit board MCB.

The outer case EDC accommodates the display module DM. The outer case EDC may be coupled to the window WM to define the exterior of the display device DD. The outer case EDC absorbs an external shock applied from the outside, and prevents foreign matters/moisture, etc., from penetrating the display module DM, thereby protecting components accommodated in the outer case EDC. Meanwhile, in an embodiment, the outer case EDC may be provided in a form in which a plurality of storage members are coupled.

The display device DD according to an embodiment may further include an electronic module including various functional modules for operating the display module DM, a power supply module for supplying power necessary for overall operations of the display device DD, and a bracket which is coupled with the display module DM or the outer case EDC and partitions the inner space of the display device DD.

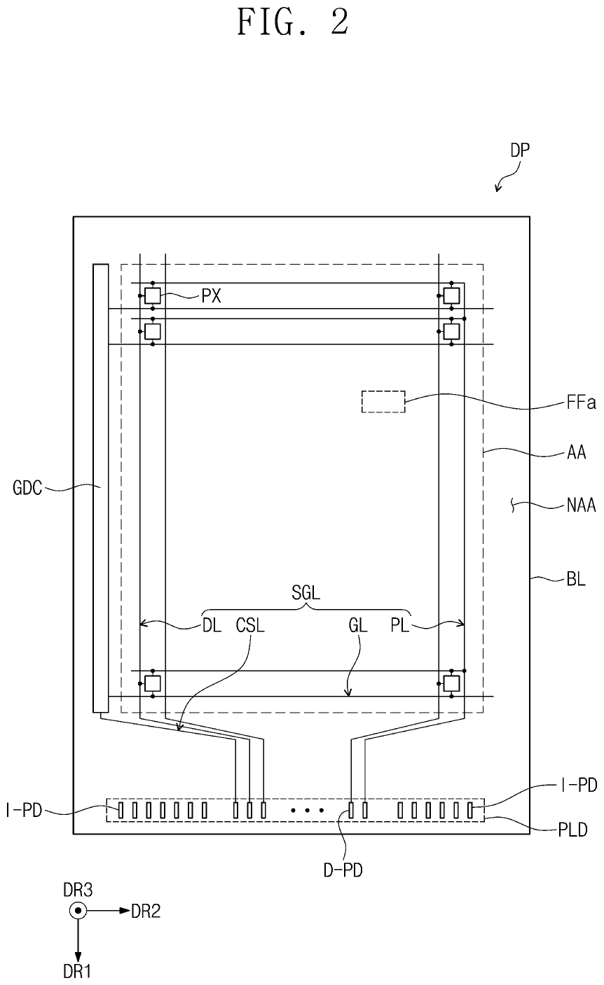

FIG. 2 is a plan view of a display panel according to an embodiment of the inventive concept. FIG. 3 is a plan view of an input-sensing unit according to an embodiment of the inventive concept.

Referring to FIG. 2, the display panel DP may include a driving circuit GDC, a plurality of signal lines SGL, and a plurality of pixels PX. The display panel DP may further include a pad portion PLD disposed on the peripheral region NAA. The pad portion PLD includes pixel pads D-PD connected to corresponding signal lines among the plurality of signal lines SGL.

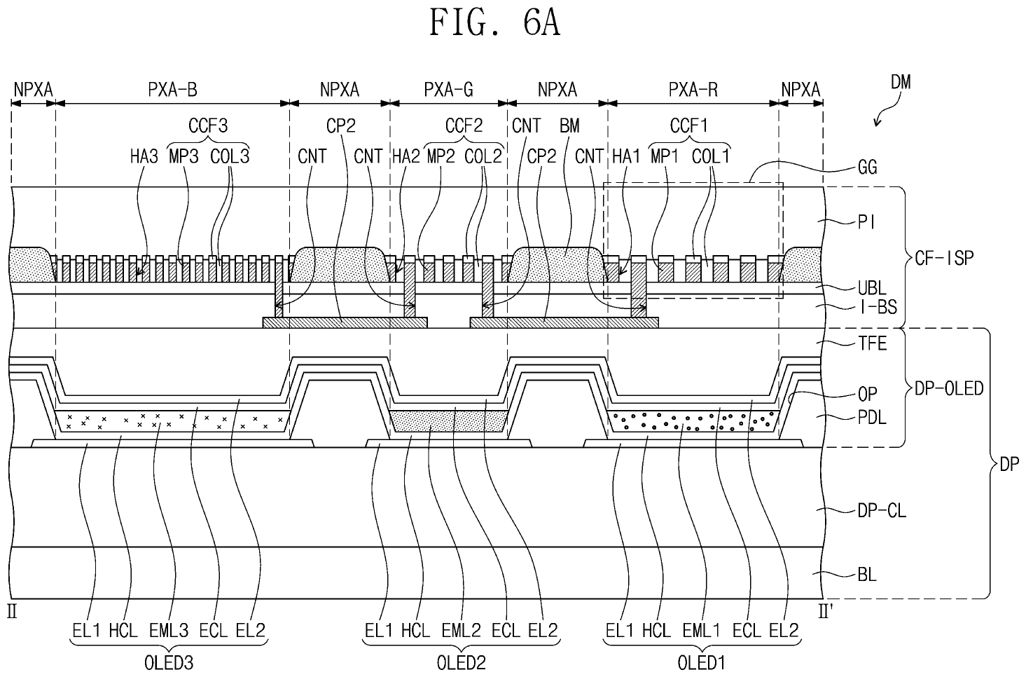

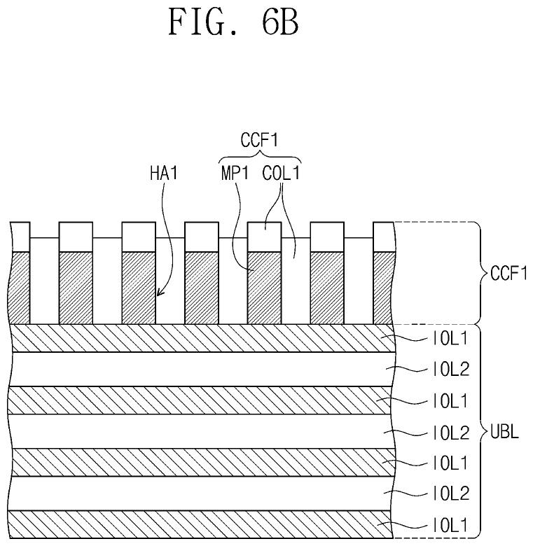

The pixels PX are disposed in the active region AA. The pixels PX respectively include organic light-emitting diodes OLED1, OLED2, and OLED3 (see FIG. 6A), and a pixel-driving circuit connected thereto. The driving circuit GDC, the signal lines SGL, the pad portion PLD, and the pixel-driving circuit may be included in a circuit element layer DP-CL illustrated in FIG. 6A.

The driving circuit GDC may include a gate-driving circuit. The gate-driving circuit generates a plurality of gate signals (hereinafter, gate signals), and sequentially outputs the gate signals to a plurality of gate lines GL (hereinafter, gate lines) to be described later. The gate-driving circuit may further output another control signal to the pixel-driving circuit.

The signal lines SGL include gate lines GL, data lines DL, a power line PL, and a control signal line CSL. One gate line of the gate lines GL is respectively connected to a corresponding pixel of the pixels PX, and one data line of the data lines DL is respectively connected to a corresponding pixel of the pixels PX. The power line PL is connected to the pixels PX. The control signal line CSL may provide the gate-driving circuit with control signals. The signal lines SGL overlap the active region AA and the peripheral region NAA.

The pad portion PLD is a portion to which the flexible circuit board FCB (see FIG. 1B) is connected, and may include pixel pads D-PD for connecting the flexible circuit board FCB (see FIG. 1B) to the display panel DP, and input pads I-PD for connecting the flexible circuit board FCB (see FIG. 1B) to the input-sensing unit CF-ISP. The pixel pads D-PD and the input pads I-PD may be provided by exposing a portion of wires disposed on the circuit element layer DP-CL (see FIG. 6A) from an insulating layer included in the circuit element layer DP-CL (see FIG. 6A).

The pixel pads D-PD are connected to corresponding pixels PX through the signal lines SGL. In addition, the driving circuit GDC may be connected to any one pixel pad of the pixel pads D-PD.

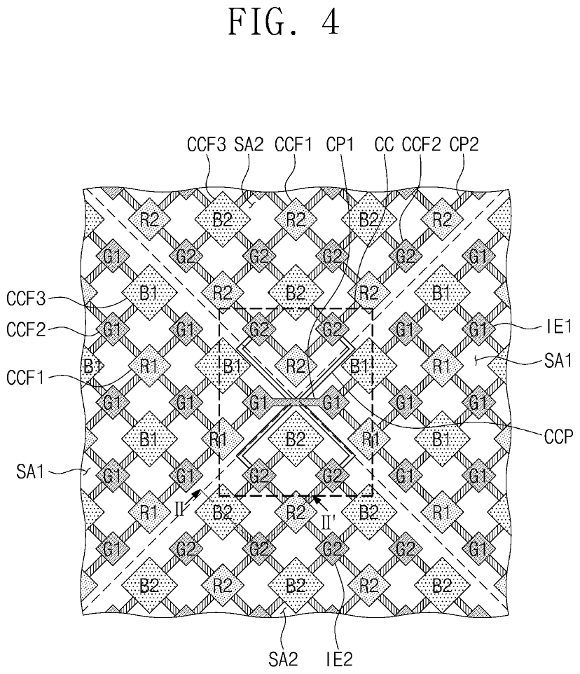

FIG. 3 is a plan view of an input-sensing unit according to an embodiment of the inventive concept. FIG. 4 is an enlarged plan view illustrating an input-sensing unit according to an embodiment of the inventive concept and corresponding to region BB illustrated in FIG. 3.

Referring to FIGS. 3 and 4, the input-sensing unit CF-ISP according to an embodiment of the inventive concept includes a plurality of color filters. The plurality of color filters may include a first color filter CCF1, a second color filter CCF2, and a third color filter CCF3. The plurality of color filters CCF1, CCF2, and CCF3 may include the first color filter CCF1 that transmits first light, the second color filter CCF2 that transmits second light having a wavelength different from that of the first light, and the third color filter CCF3 that transmits third light having a wavelength different from those of the first light and the second light. The first color filter CCF1 may be a red color filter, the second color filter CCF2 may be a green color filter, and the third color filter CCF3 may be a blue color filter. The first to third color filters CCF1, CCF2, and CCF3 will be described later in detail.

First sensing regions SA1 may be arranged in the first and second directions DR1 and DR2. Second sensing regions SA2 may be arranged in the first and second directions DR1 and DR2, and disposed spaced apart from the first sensing regions SAL The first sensing regions SA1 and the second sensing regions SA2 may be disposed in the active region AA.

A plurality of color filters may be disposed in each of the first sensing regions SA1 and the second sensing regions SA2. A plurality of color filters R1, G1, and B1 may be disposed in each of the first sensing regions SAL In each of the first sensing regions SA1, the plurality of color filters R1, G1, and B1 may be electrically connected to each other to form a first sensing electrode IE1. In each of the second sensing regions SA2, a plurality of color filters R2, G2, and B2 may be disposed. In the second sensing regions SA2, the plurality of color filters R2, G2, and B2 may be electrically connected to each other to form a second sensing electrode IE2.

A plurality of first sensing electrode IE1 may be provided and arranged in the first and second directions DR1 and DR2. Here, the first sensing electrodes IE1 arranged in the second direction DR2 may be electrically connected to each other by first connecting patterns CP1. The first sensing electrodes IE1 connected by the first connecting patterns CP1 may form a single sensing electrode row. In an embodiment of the inventive concept, the sensing electrode row may be provided in plurality and arranged in the first direction DR1. A plurality of sensing electrode rows IE1-1 to IE1-5 may be respectively connected to first signal lines SL1-1 to SL1-5. The first signal lines SL1-1 to SL1-5 may be disposed in the peripheral region NAA.

A plurality of second sensing electrodes IE2 may be provided and arranged in the first and second directions DR1 and DR2. Here, the second sensing electrodes IE2 arranged in the first direction DR1 may be electrically connected to each other by conductive patterns CCP. The second sensing electrodes IE2 connected by the conductive patterns CCP may form a single sensing electrode column. As an example of the inventive concept, the sensing electrode column may be provided in plurality, and may be arranged in the second direction DR2. A plurality of sensing electrode columns IE2-1 to IE2-4 may be respectively connected to second signal lines SL2-1 to SL2-4. The second signal lines SL2-1 to SL2-4 may be disposed in the peripheral region NAA.

As an example of the inventive concept, the input-sensing unit CF-ISP may further include third signal lines connected to the sensing electrode columns IE2-1 to IE2-4. In this case, the second signal lines SL2-1 to SL2-4 may be connected to ends of the sensing electrode columns IE2-1 to IE2-4, and the third signal lines may be connected to the other ends of the sensing electrode columns IE2-1 to IE2-4.

The second sensing electrodes IE2 may be electrically insulated from the first sensing electrodes IE1. In particular, the first and second sensing electrodes IE1 and IE2 may be electrically insulated by the first connecting pattern CP1 and the conductive pattern CCP which are respectively disposed on different layers.

FIG. 3 illustrates the first and second sensing regions SA1 and SA2 according to an embodiment, but the shapes thereof are not limited thereto. In an embodiment of the inventive concept, the first and second sensing regions SA1 and SA2 are exemplarily illustrated as each having a rhombus shape, but an embodiment of the inventive concept is not limited thereto. Thus, the first and second sensing regions SA1 and SA2 may each have a polygonal shape.

The first signal lines SL1-1 to SL1-5 are respectively connected to ends of the sensing electrode rows IE1-1 to IE1-5. In an embodiment of the inventive concept, the input-sensing unit CF-ISP may further include signal lines connected to the other ends of the sensing electrode rows IE1-1 to IE1-5.

The input-sensing unit CF-ISP may include input pads I-PD extending from ends of the first signal lines SL1-1 to SL1-5 and the second signal lines SL2-1 to SL2-4, and disposed in the peripheral region NAA.

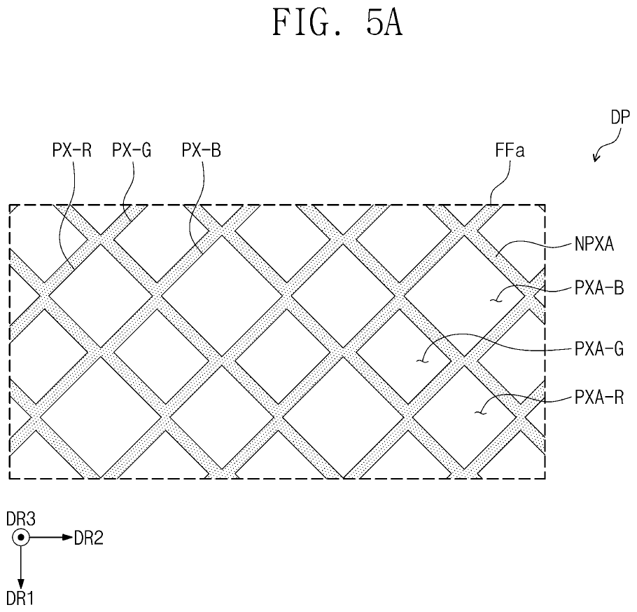

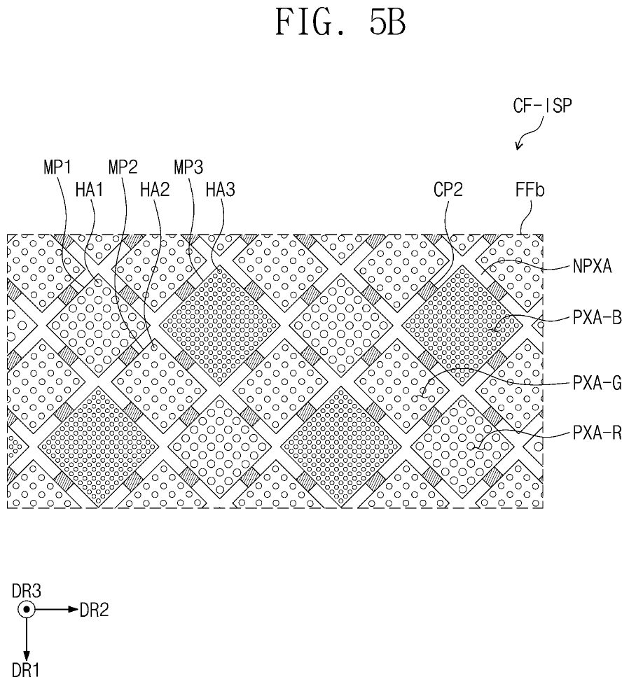

FIG. 5A is an enlarged plan view illustrating a display panel according to an embodiment of the inventive concept, and corresponding to region FFa illustrated in FIG. 2, FIG. 5B is an enlarged plan view illustrating an input-sensing unit according to an embodiment of the inventive concept, and corresponding to region FFb illustrated in FIG. 3, FIG. 6A is a cross-sectional view of a display module according to an embodiment of the inventive concept, and taken along II-II′ illustrated in FIG. 4, and FIG. 6B is an enlarged cross-sectional view of part GG illustrated in FIG. 6A.

Referring to FIG. 5A, the display panel DP includes a plurality of pixel regions. In an embodiment, the plurality of pixel regions may include a plurality of first pixel regions PX-R, a plurality of second pixel regions PX-G, and a plurality of third pixel regions PX-B, and the plurality of first pixel regions PX-R, the plurality of second pixel regions PX-G, and the plurality of third pixel regions PX-B may have sizes different from each other. That is, the second pixel regions PX-G may be smaller than the first pixel regions PX-R and the third pixel regions PX-B, and the first pixel regions PX-R may be smaller than the third pixel regions PX-B. In an embodiment, the first pixel regions PX-R may be pixel regions for outputting red light, the second pixel regions PX-G may be pixel regions for outputting green light, and the third pixel regions PX-B may be pixel regions for outputting blue light.

The first pixel regions PX-R may be arranged along the first direction DR1 and the second direction DR2. The first pixel regions PX-R and the third pixel regions PX-B may be alternately repeated and arranged along the first direction DR1 and the second direction DR2. The arrangement structure of the first to third pixel regions PX-R, PX-G, and PX-B illustrated in FIG. 5A is exemplarily illustrated, and an embodiment of the inventive concept is not limited thereto. For example, in another embodiment of the inventive concept, the first pixel regions PX-R, the second pixel regions PX-G, and the third pixel regions PX-B may be arranged in the form of being alternately disposed along the second direction DR2. In addition, the first to third pixel regions PX-R, PX-G, and PX-B are exemplarily illustrated as each having a rectangular shape, but an embodiment of the inventive concept is not limited thereto. Thus, the shape of each of the first to third pixel regions PX-R, PX-G, and PX-B may be variously changed into a polygon, a circle, an oval, etc. In another embodiment, the shapes of the first to third pixel regions PX-R, PX-G, and PX-B may be different from each other. That is, the second pixel regions PX-G may have a hexagonal shape or an octagonal shape, and the first and the third pixel regions PX-R and PX-B may have a tetragonal shape.

In addition, FIG. 5A exemplarily illustrates that the size of the second pixel regions PX-G is smaller than the sizes of the first pixel regions PX-R and the third pixel regions PX-B, but an embodiment of the inventive concept is not limited thereto. For example, in another embodiment of the inventive concept, the first to third pixel regions PX-R, PX-G, and PX-B may have the same size.

The first pixel regions PX-R may each include a first light-emitting region PXA-R in which light is output. The second pixel regions PX-G may each include a second light-emitting region PXA-G in which light is output. The third pixel regions PX-B may each include a third light-emitting region PXA-B in which light is output. The light-emitting regions PXA-R, PXA-G, and PXA-B and a non-light-emitting region NPXA adjacent to the light-emitting regions PXA-R, PXA-G, and PXA-B may be defined in the display panel DP. The non-light-emitting region NPXA may be disposed so as to surround the light-emitting regions PXA-R, PXA-G, and PXA-B

Hereinafter, an input-sensing unit according to an embodiment of the inventive concept will be described with reference to FIGS. 5A to 6B.

According to the inventive concept, the input-sensing unit CF-ISP may include the first to third color filters CCF1, CCF2, and CCF3. The first to third color filters CCF1, CCF2, and CCF3 may each be a band pass color filter which may selectively transmit light in a specific wavelength band through a surface plasmon resonance (SPR) phenomenon. Meanwhile, the surface plasmon resonance phenomenon indicates a phenomenon that when light is incident on a metal surface including nano-sized holes arranged with a certain period, light with a specific wavelength and free electrons on the metal surface cause resonance to allow light with a specific wavelength to be transmitted. Only light with a specific wavelength capable of generating the surface plasmon resonance by incident light may transmit the holes, and all other light may be reflected by the metal surface.

The first to third color filters CCF1, CCF2, and CCF3 may respectively include first to third metal patterns MP1, MP2, and MP3 in which a plurality of first to third holes HAL HA2, and HA3 having certain periods are respectively defined. The first to third metal patterns MP1, MP2, and MP3 may respectively overlap a plurality of pixel regions PX-R, PX-G, and PX-B. In an embodiment, the first metal patterns MP1 may overlap the plurality of first pixel regions PX-R, the second metal patterns MP2 may overlap the plurality of second pixel regions PX-G, and the third metal patterns MP3 may overlap the plurality of third pixel regions PX-B.

The first to third metal patterns MP1, MP2, and MP3 may respectively overlap light-emitting regions PXA-R, PXA-G, and PXA-B of the plurality of pixel regions PX-R, PX-G, and PX-B. In an embodiment, the first to third metal patterns MP1, MP2, and MP3 may overlap the light-emitting regions PXA-R, PXA-G, and PXA-B of the plurality of pixel regions PX-R, PX-G, and PX-B. However, an embodiment of the inventive concept is not limited thereto, and the first to third metal patterns MP1, MP2, and MP3 may also overlap the non-light-emitting region NPXA partially.

The first to third metal patterns MP1, MP2, and MP3 may respectively include the plurality of holes HAL HA2, and HA3 having different planar arrangements. The first metal patterns MP1 may include a plurality of first holes HAL the second metal patterns MP2 may include a plurality of second holes HA2, and the third metal patterns MP3 may include a plurality of third holes HA3. The plurality of first holes HA1, the plurality of second holes HA2, and the plurality of third holes HA3 may each have a circular shape, when viewed from a plane. However, the shapes of the first to third holes HA1, HA2, and HA3 are not limited thereto. The shapes of the plurality of first to third holes HAL HA2, and HA3 may be variously changed into a polygonal shape, an oval shape, a stripe shape, etc.

In an embodiment, the first to third metal patterns MP1, MP2, and MP3, which respectively overlap the plurality of first to third pixel regions PX-R, PX-G, and PX-B, may have planar arrangements different from each other. More specifically, the plurality of first to third holes HAL HA2, and HA3 defined in the first to third metal patterns MP1, MP2, and MP3 may have planar arrangements different from each other. For example, the plurality of first holes HA′ defined in the first metal patterns MP1 overlapping the plurality of first pixel regions PX-R may be different in planar arrangement from the plurality of second holes HA2 defined in the second metal patterns MP2 overlapping the plurality of second pixel regions PX-G. The plurality of third holes HA3 defined in the third metal patterns MP3 overlapping the plurality of third pixel regions PX-B may be different in planar arrangement from the plurality of first holes HA′ defined in the first metal patterns MP1 overlapping the plurality of first pixel regions PX-R, and the plurality of second holes HA2 defined in the second metal patterns MP2 overlapping the plurality of second pixel regions PX-G.

In an embodiment, the width, the arrangement period, and the shape of each of the plurality of first holes HAL the plurality of second holes HA2, and the plurality of third holes HA3 may be variously changed for an effective light-filtering effect. More specifically, the wavelength (Amax) of light transmitted by the surface plasmon resonance may be calculated by Mathematical Equation 1 below. Mathematical Equation 1 may be applied to metal patterns having a square hole array. The wavelength (λₘₐₓ) of transmitted light may represent the central wavelength of light at which an extraordinary optical transmission (EOT) phenomenon caused by the surface plasmon resonance occurs.

$${λ}_{max} = \frac{P}{\sqrt{{i}^{2} + {j}^{2}}} \sqrt{\frac{{ε}_{m} {ε}_{d}}{{ε}_{m} + {ε}_{d}}} \qquad [ Mathematical Equation 1 ]$$

In Mathematical Equation 1, εₘ is the permittivity of a metal, Ed is the permittivity of a dielectric, P is the spacing between holes in the plurality of holes having nano sizes, and i and j are the scattering orders of a two dimensional array, which indicate a unit vector value having the directional information on transmitted light. As in Mathematical Equation 1, the wavelength of light at which the extraordinary optical transmission occurs may be selectively controlled by changing the widths, the arrangement periods, or the shapes of the plurality of first to third holes HAL HA2, and HA3 defined in the metal patterns MP1, MP2, and MP3 according to an embodiment of the inventive concept. In addition, the wavelength of transmitted light may be controlled by changing the type of a metal constituting the metal patterns MP1, MP2, and MP3.

The first to third metal patterns MP1, MP2, and MP3 may be composed of various materials. In an embodiment, the first to third metal patterns MP1, MP2, and MP3 may each include a metal. For example, the first to third metal patterns MP1, MP2, and MP3 may each include a metal selected from the group consisting of aluminum (Al), silver (Ag), gold (Au), platinum (Pt), nickel (Ni), copper (Cu), indium (In), ruthenium (Ru), palladium (Pd), rhodium (Rh), iridium (Ir), osmium (Os), tungsten (W), and a combination thereof. However, an embodiment of the inventive concept is not limited thereto. In an embodiment, the first to third metal patterns MP1, MP2, and MP3 may each include aluminum (Al), silver (Ag), gold (Au), or copper (Cu).

In an embodiment, the plurality of first to third holes HA1, HA2, and HA3 may be formed through various processes. For example, the plurality of first to third holes HA1, HA2, and HA3 may be formed through a process such as electron beam lithography (EBL), laser interference lithography (LIL), nanoimprint, ion beam method, focused ion beam (FIB) milling, etc., but an embodiment of the inventive concept is not limited thereto.

A typical method for manufacturing color filters includes adding dyes and pigments, and thus has a limitation in that due to the inherent wavelength absorption characteristics of materials, color filters respectively corresponding to red, green, and blue have to be manufactured, and also has a limitation in that the color filters are manufactured based on an organic material, resulting in poor stability against chemical and thermal reactions. In addition, the typical method is disadvantageous in that since an input sensor process and a color filter process are separated, a tact time and a production cost are increased, and a product is thickened as well.

According to the inventive concept, a color filter that transmits light in a predetermined wavelength band may be formed by using metal patterns in which nano-sized holes having periodicity are defined. In the case of a metal thin film composed of nano-sized holes having periodicity, a surface plasmon resonance phenomenon may occur in the thin film, and thus light in a predetermined wavelength band may be transmitted therethrough. In addition, a transmittance wavelength band may be variously changed by changing the width, period, thickness, shape, etc., of the holes. Accordingly, compared to typical color filters using pigments or dyes, material limitations may be overcome, and various color filters may be formed through a single process, thereby simplifying the process and shortening the tact time. The reliability of a display device may be improved by applying an inorganic material-based material, such as metal, having excellent chemical stability. In addition, by forming a color filter-integrated input sensor in which a color filter is integrated into the input sensing unit, it is possible not only to reduce the thickness and tact time of a display device, but also to ensure the wide formation region for sensing electrodes in a light-emitting region, thereby providing a display device having excellent touch performance.

Referring to FIG. 6A, a display panel DP may include a base layer BL, a circuit element layer DP-CL disposed on the base layer BL, and a display element layer DP-OLED.

The base layer BL may include a synthetic resin film. The synthetic resin film is formed on a work substrate used in manufacture of the display panel DP. Then, a conductive layer and an insulating layer, etc., are formed on the synthetic resin layer. When the work substrate is removed, the synthetic resin layer corresponds to the base layer BL. The synthetic resin layer may be a polyimide-based resin layer, and the material thereof is not specially limited thereto. In addition, the base layer BL may include a glass substrate, a metal substrate, an organic/inorganic substrate, etc.

The circuit element layer DP-CL includes at least one insulating layer and a circuit element. Hereinafter, the insulating layer included in the circuit element layer DP-CL is referred to as an intermediate insulating layer. The intermediate insulating layer includes at least one intermediate inorganic film and at least one intermediate organic film. The circuit element includes a signal line, and a driving circuit of a pixel. The circuit element layer DP-CL may be formed through a process for forming an insulating layer, a semiconductor layer, and a conductive layer by coating, deposition, etc., and a process for patterning an insulating layer, a semiconductor layer, and a conductive layer by a photolithography process.

The display element layer DP-OLED my include a pixel-defining film PDL and organic light-emitting diodes OLED1, OLED2, and OLED3. The pixel-defining film PDL may include an organic material. A first electrode EL1 is disposed on the circuit element layer DP-CL. The pixel-defining film PDL is formed on the first electrode ELL A pixel opening OP is defined on the pixel-defining film PDL. The pixel opening OP of the pixel-defining film PDL exposes at least a portion of the first electrode ELL The pixel-defining film PDL may be omitted in an embodiment of the inventive concept.

Light-emitting regions PXA-R, PXA-G and PXA-B, and a non-light-emitting region NPXA adjacent to the light-emitting regions PXA-R, PXA-G and PXA-B, may be defined in the display panel DP. The non-light-emitting region NPXA may be disposed so as to surround the light-emitting regions PXA-R, PXA-G and PXA-B. In the present embodiment, the light-emitting regions PXA-R, PXA-G and PXA-B are defined corresponding to a partial region of the first electrode EL1 exposed by the pixel opening OP.

A hole control layer HCL may be disposed in both the light-emitting regions PXA-R, PXA-G, and PXA-B, and the non-light-emitting region NPXA. Light-emitting layers EML1, EML2, and EML3, which generate light, are disposed on the hole control layer HCL. The light-emitting layers EML1, EML2, and EML3 may be disposed in a region corresponding to the pixel opening OP. That is, the light-emitting layers EML1, EML2, and EML3 may be separated and formed in the light-emitting regions PXA-R, PXA-G, and PXA-B, respectively. The light-emitting layers EML1, EML2, and EML3 may include an organic material or an inorganic material. The light-emitting layers EML1, EML2, and EML3 may generate predetermined colored light. For example, the light-emitting layers EML1, EML2, and EML3 may generate red light, green light, and blue light, respectively. Accordingly, the light-emitting regions PXA-R, PXA-G, and PXA-B are defined as regions in which light is generated, and the non-light-emitting region NPXA is defined as a region in which light is not generated.

In the present embodiment, the patterned light-emitting layers EML1, EML2, and EML3 are exemplarily illustrated, but a single light-emitting layer may be disposed on entire surfaces of the light-emitting regions PXA-R, PXA-G, and PXA-B. In this case, the light-emitting layer may generate white light. In addition, the light-emitting layers EML1, EML2, and EML3 may have a multi-layered structure referred to as tandem.

An electron control layer ECL is disposed on the light-emitting layers EML1, EML2, and EML3. Although not shown separately, the electron control layer ECL may be formed in both the light-emitting regions PXA-R, PXA-G, and PXA-B, and the non-light-emitting region NPXA. A second electrode EL2 is disposed on the electron control layer ECL. The second electrode EL2 is disposed in both the light-emitting regions PXA-R, PXA-G, and PXA-B and the non-light-emitting region NPXA.

An encapsulation layer TFE is disposed on the second electrode EL2. The encapsulation layer TFE seals the display element layer DP-OLED. The encapsulation layer TFE includes at least one insulating layer. The encapsulation layer TFE according to an embodiment of the inventive concept may include at least one inorganic film (hereinafter, inorganic encapsulation film). The encapsulation layer TFE according to an embodiment of the inventive concept may include at least one organic film (hereinafter, organic encapsulation film), and at least one inorganic encapsulation film.

The inorganic encapsulation film protects the display element layer DP-OLED from moisture/oxygen, and the organic encapsulation film protects the display element layer DP-OLED from foreign matters such as dust particles. The inorganic encapsulation film may include a silicon nitride layer, a silicon oxynitride layer, a silicon oxide layer, a titanium oxide layer, an aluminum oxide layer, etc., and an embodiment of the inventive concept is not limited thereto. The organic encapsulation film may include an acryl-based organic film, and is not specially limited thereto.

FIG. 6A illustrates that the light-emitting regions PXA-R, PXA-G, and PXA-B have sizes different from each other. That is, as an example, it is exemplarily illustrated that the size of the second light-emitting region PXA-G is smaller than those of the first and third light-emitting regions PXA-R and PXA-B, and the size of the first light-emitting region PXA-R is smaller than that of the third light-emitting region PXA-B, but an embodiment of the inventive concept is not limited thereto. For example, in another embodiment of the inventive concept, the first to third light-emitting regions PXA-R, PXA-G, and PXA-B may have the same size.

An input-sensing unit CF-ISP may be disposed on the display panel DP. More specifically, the input-sensing unit CF-ISP may be directly disposed on the encapsulation layer TFE of the display panel DP. The input-sensing unit CF-ISP may include a base layer I-BS, an optical layer UBL, and a plurality of color filters CCF1, CCF2, and CCF3. The base layer I-BS may be disposed on the encapsulation layer TFE, and may include an inorganic material. For example, the base layer I-BS may include a silicon nitride layer, but an embodiment of the inventive concept is not limited thereto. An inorganic film disposed on the uppermost side of the encapsulation layer TFE may also include silicon nitride. In this case, the inorganic film disposed on the uppermost side of the encapsulation layer TFE, and the base layer I-BS may be formed under different deposition conditions.

Referring to FIGS. 6A and 6B, an optical layer UBL may be disposed on the base layer I-BS. The optical layer UBL may include a plurality of inorganic films having refractive indices different from each other. FIG. 6B illustrates that the optical layer UBL includes four first inorganic films IOL1 and three second inorganic films IOL2, but an embodiment of the inventive concept is not limited thereto.

The optical layer UBL may include the first inorganic films IOL1 and the second inorganic film IOL2. More specifically, the optical layer UBL may have a configuration in which the first inorganic film IOL1 having a first refractive index and the second inorganic film IOL2 having a second refractive index different from the first refractive index are alternately stacked. In an embodiment, the first inorganic film IOL1 and the second inorganic film IOL2 may be in contact with each other. In an embodiment, the thickness of the optical layer UBL may be about 0.7 μm to about 1.5 μm. For example, the thickness of the optical layer UBL may be about 1.0 μm. However, the thickness of the optical layer UBL is not limited thereto.

In an embodiment, the first refractive index may be greater than the second refractive index. The second refractive index may be about 1.55 to about 1.65, and the first refractive index may be about 1.71 to about 1.81. For example, the second refractive index may be about 1.60, and the first refractive index may be about 1.76. However, an embodiment of the inventive concept is not limited thereto. When the first refractive index and the second refractive index do not respectively satisfy the aforementioned ranges, the number of the thin films for reflecting light of a specific wavelength in an ultraviolet range increases to cause manufacturing costs to be increased, and visible light transmittance is lowered to cause the optical characteristics of a display device to be degraded.

The thicknesses of the first inorganic film IOL1 and the second inorganic film IOL2 may be the same as or different from each other. In an embodiment, the thickness of each of the first inorganic film IOL1 and the second inorganic film IOL2 may be about 100 nm or less, preferably, about 50 nm or less. However, the thickness of each of the first inorganic film IOL1 and the second inorganic film IOL2 is not limited thereto. When the thicknesses of the first inorganic film IOL1 and the second inorganic film IOL2 satisfy the above ranges, excellent UV blocking effect may be expected, and the extraction effect of light emitted from a light-emitting element of a display device is not reduced, thereby maximizing the effect of improving the light efficiency of the display device.

In an embodiment, the first inorganic film IOL1 and the second inorganic film IOL2 may each include, without any particular limitations, a material that satisfies the first refractive index and the second refractive index as described above. For example, the first inorganic film IOL1 and the second inorganic film IOL2 may each include at least any one of metal, metal oxide, metal nitride, metal oxynitride, metal carbide, metal carbonitride, metal sulfide, or metal selenide. For example, the first inorganic film IOL1 and the second inorganic film IOL2 may each include at least any one of an oxide, a nitride, an oxynitride, a carbide, a carbonitride, a sulfide, or a selenide of metal selected from silicon, aluminum, zinc, titanium, tantalum, hafnium, zirconium, cerium, tungsten, tin or copper. However, an embodiment of the inventive concept is not limited thereto.

The optical layer UBL may be disposed so as to overlap the entirety of the light-emitting regions PXA-R, PXA-G, and PXA-B and the non-light-emitting region NPXA. At least some of the optical layer UBL may be connected to each other on the base layer I-BS, and the optical layer UBL may thus have an integrated shape. However, an embodiment of the inventive concept is not limited thereto, and unlike FIG. 6A, in an embodiment, the optical layer UBL may be patterned and provided between light-blocking patterns BM. That is, the optical layer UBL may be separated and formed overlapping each of the light-emitting regions PXA-R, PXA-G, and PXA-B.

The first and second inorganic films IOL1 and IOL2 may be each formed by using sputtering, chemical vapor deposition (CVD), plasma enhanced chemical vapor deposition (PECVD), atomic layer deposition, etc., but an embodiment of the inventive concept is not limited thereto.

An organic light-emitting element may be degraded due to a series of photo reactions caused by absorption of ultraviolet photons, and accordingly, the mechanical and optical characteristics of a display device may be deteriorated. In addition, outgassing may occur in the organic light-emitting device due to ultraviolet rays, thereby causing pixel shrinkage that a light-emitting region gradually shrinks.

The input-sensing unit CF-ISP according to an embodiment of the inventive concept may include an optical layer UBL having a multi-layered thin film structure in which a plurality of inorganic films having different refractive indices are alternately stacked, and thus function to block ultraviolet rays. More specifically, the optical layer UBL may be formed which includes multi-layered thin films in which the first inorganic film IOL1 having a first refractive index and the second inorganic film IOL2 having a second refractive index different from the first refractive index are alternately stacked, and which is capable of functioning to block ultraviolet rays. When the optical layer UBL is applied to a display device, ultraviolet rays incident onto an organic light-emitting element may be effectively blocked, thereby improving the optical characteristics of the display device. In addition, the reliability of the display device may be further improved by enabling low outgassing by virtue of ultraviolet-blocking characteristics.

The plurality of color filters CCF1, CCF2, and CCF3 may be disposed on the optical layer UBL. The plurality of color filters CCF1, CCF2, and CCF3 may include a first color filter CCF1 that transmits first light, a second color filter CCF2 that transmits second light having a wavelength different from that of the first light, and a third color filter CCF3 that transmits third light having a wavelength different from those of the first light and the second light. In an embodiment, the first light to the third light may have wavelength ranges different from each other. For example, the first light may be red light having a wavelength range of about 625 nm to about 675 nm. For example, the second light may be green light having a wavelength range of about 500 nm to about 570 nm. For example, the third light may be blue light having a wavelength range of about 410 nm to about 480 nm.

The first to third color filters CCF1, CCF2, and CCF3 may be disposed respectively corresponding to light-emitting regions PXA-R, PXA-G, and PXA-B. For example, the first color filter CCF1 may be disposed overlapping the first light-emitting region PXA-R, the second color filter CCF2 may be disposed overlapping the second light-emitting region PXA-G, and the third color filter CCF3 may be disposed overlapping the third light-emitting region PXA-B.

The first to third color filters CCF1, CCF2, and CCF3 may respectively include first to third metal patterns MP1, MP2, and MP3, and first to third oxide layers COL1, COL2, and COL3. A plurality of first to third holes HAL HA2, and HA3 may be respectively defined in the first to third metal patterns MP1, MP2, and MP3. A plurality of first holes HA′ may be defined in the first metal pattern MP1, a plurality of second holes HA2 may be defined in the second metal pattern MP2, and a plurality of holes HA3 may be defined in the third metal pattern MP3.

In an embodiment, the thickness of each of the first to third metal patterns MP1, MP2, and MP3 included in the input-sensing unit CF-ISP may be about 1 nm to about 300 nm. The thickness of each of the first to third metal patterns MP1, MP2, and MP3 may be equal to each other. However, an embodiment of the inventive concept is not limited thereto, and the thicknesses of the first to third metal patterns MP1, MP2, and MP3 may be different from each other.

The plurality of first to third holes HAL HA2, and HA3 may respectively penetrate the first to third metal patterns MP1, MP2, and MP3. However, an embodiment of the inventive concept is not limited thereto, and the plurality of first to third holes HAL HA2, and HA3 may not respectively penetrate the first to third metal patterns MP1, MP2, and MP3. In this case, the depths of the plurality of first to third holes HAL HA2, and HA3 may be respectively smaller than the thicknesses of the first to third metal patterns MP1, MP2, and MP3.

The first to third oxide layers COL1, COL2, and COL3 may be respectively disposed on the first to third metal patterns MP1, MP2, and MP3. The first to third oxide layers COL1, COL2, and COL3 may be respectively disposed on the first to third metal patterns MP1, MP2, and MP3, while respectively filling the plurality of first to third holes HAL HA2, and HA3. The first oxide layer COL1 may be disposed on the first metal pattern MP1 while filling a plurality of first holes HAL the second oxide layer COL2 may be disposed on the second metal pattern MP2 while filling a plurality of second holes HA2, and the third oxide layer COL3 may be disposed on the third metal pattern MP3 while filling a plurality of third holes HA3.

In an embodiment, the first to third oxide layers COL1, COL2, and COL3 may each include a dielectric material. For example, the first to third oxide layers COL1, COL2, and COL3 may each include a dielectric material such as lithium fluoride (LiF), or silicon dioxide (SiO₂), or a dielectric material which is a transparent conductive oxide (TCO) such as aluminum oxide (Al₂O₃), magnesium oxide (MgO), zinc oxide (ZnO), zinc sulfide (ZnS), indium zinc oxide (IZO), indium tin zinc oxide (ITZO), or indium tin oxide (ITO). However, an embodiment of the inventive concept is not limited thereto.

In an embodiment, the first to third oxide layers COL1, COL2, and COL3 may each include a low-permittivity (low-k) material. Accordingly, the first to third oxide layers COL1, COL2, and COL3 may each have low-permittivity characteristics. When the first to third oxide layers COL1, COL2, and COL3 may each include a low-permittivity material, the wavelength selectivity of the first to third color filters CCF1, CCF2, and CCF3 may become higher. That is, the first to third color filters CCF1, CCF2, and CCF3 may exhibit excellent full width of half maximum (FWHM) characteristics, so that the transmittance and the color purity of transmitted light may be improved. Although not shown, a separate oxide layer may be further disposed under the first to third metal patterns MP1, MP2, and MP3.

Meanwhile, FIGS. 6A and 6B illustrate that the upper surfaces of the first to third oxide layers COL1, COL2, and COL3 are not constant, but an embodiment of the inventive concept is not limited thereto. For example, the upper surfaces of the first to third oxide layers COL1, COL2, and COL3 may each have a flat surface. That is, the first to third oxide layers COL1, COL2, and COL3 may be respectively disposed on the first to third metal patterns MP1, MP2, and MP3 so as to have flat surfaces. Accordingly, the respective upper surfaces of the first to third oxide layers COL1, COL2, and COL3 may be parallel to the upper surfaces of the first to third metal patterns MP1, MP2, and MP3. In addition, it is illustrated that in the first to third oxide layers COL1, COL2, and COL3, portions that fill the inside of the first to third holes HAL HA2, and HA3, and portions disposed on the first to third metal patterns MP1, MP2, and MP3 are separated, but unlike this illustration, the first to third oxide layers COL1, COL2, and COL3 may be each formed so that portions that fill the inside of the first to third holes HAL HA2, and HA3, and portions disposed on the first to third metal patterns MP1, MP2, and MP3 may respectively have integrated shapes.

Referring to FIGS. 4, 5B, and 6A, the first to third color filters CCF1, CCF2, and CCF3 included in the second sensing electrode IE2 may be electrically connected to each other by the second connecting patterns CP2. In an embodiment, the first to third color filters CCF1, CCF2, and CCF3 may be electrically connected to each other, thereby constituting the second sensing electrode IE2. The first to third color filters CCF1, CCF2, and CCF3 may be connected to a portion of the second connecting patterns CP2 through contact holes CNT, respectively. The contact holes CNT may penetrate the optical layer UBL and the base layer I-BS which are disposed between the first to third color filters CCF1, CCF2, and CCF3 and the second connecting patterns CP2. Meanwhile, the second sensing electrode IE2 is exemplarily described in FIG. 6A, but an embodiment of the inventive concept is not limited thereto. The description above may be equally applied to the first sensing electrode IE1. That is, the first to third color filters CCF1, CCF2, and CCF3 included in the first sensing electrode IE1 may be electrically connected to each other by the second connecting patterns CP2.

The second connecting patterns CP2 may be formed of the same material as the color filters CCF1, CCF2, and CCF3. For example, the second connecting patterns CP2 may be formed of the same material as the metal patterns MP1, MP2, and MP3 of the color filters CCF1, CCF2, and CCF3. However, an embodiment of the inventive concept is not limited thereto.

A light-blocking pattern BM may be disposed on the optical layer UBL. The light-blocking pattern BM may overlap a pixel-defining film PDL. Accordingly, the light-blocking pattern BM may not overlap the pixel opening OP defined in the pixel-defining film PDL. Accordingly, the light-blocking pattern BM may not overlap the light-emitting regions PXA-R, PXA-G, and PXA-B. The light-blocking pattern BM may partially overlap the first to third color filters CCF1, CCF2, and CCF3 in the non-light-emitting region NPXA.

The light-blocking pattern BM may be a pattern having a black color, and may be a black matrix. The light-blocking pattern BM may include a black coloring agent. The black coloring agent may include black dyes, or black pigments. The black coloring agent may include carbon black, metal such as chromium, or an oxide thereof.

The input-sensing unit CF-ISP may further include a protective layer PI that covers the plurality of color filters CCF1, CCF2, and CCF3 and the light-blocking pattern BM. The protective layer PI may be a planarization layer. That is, the protective layer PI may smooth a level difference between the plurality of color filters CCF1, CCF2, and CCF3 and the light-blocking pattern BM, and thus enable the upper surface of the input-sensing unit CF-ISP to be planarized.

The protective layer PI may be formed of a transparent polymer resin. The protective layer PI may further include a functional material in addition to the polymer resin. For example, the protective layer PI may further include functional materials such as a light absorber, an antioxidant, and a scattering agent.

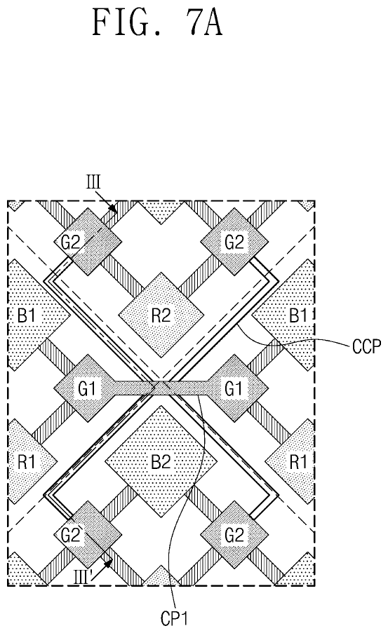

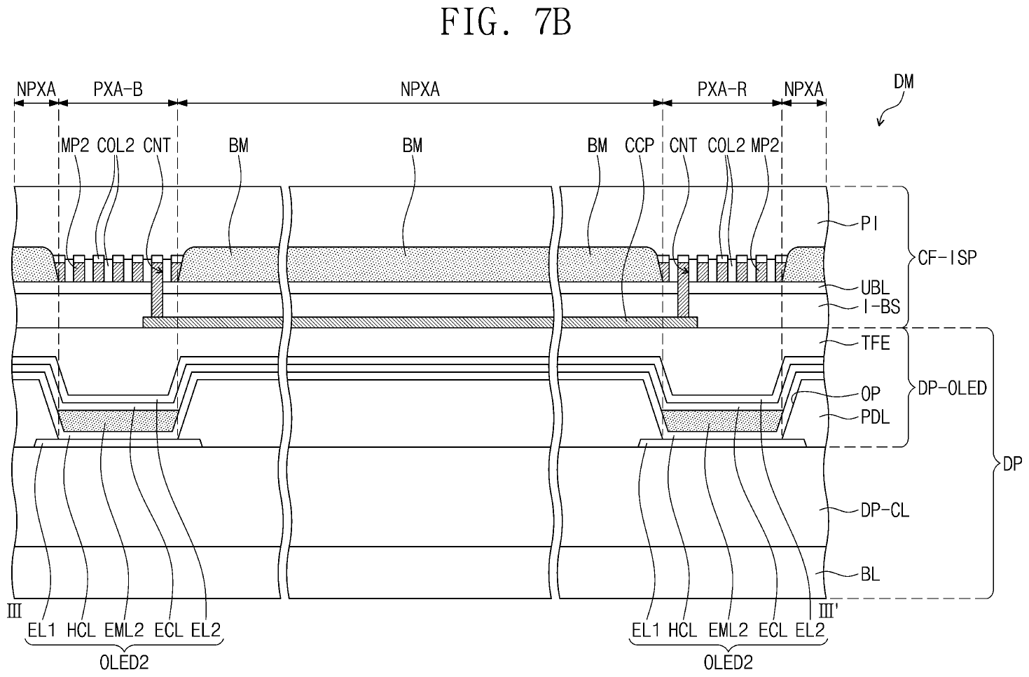

FIG. 7A is a plan view in which the region CC of FIG. 4 is enlarged, and FIG. 7B is a cross-sectional view, of a display module according to an embodiment of the inventive concept, taken along cutting line III-III′ illustrated in FIG. 7A. FIG. 7A illustrates an embodiment in which the first connecting patterns CP1 and the conductive patterns CCP overlap on a plane.

Referring to FIGS. 4, 7A, and 7B, at least one color filter of the first sensing electrode IE1 may be electrically connected to at least one color filter adjacent thereto of the first sensing electrode IE1 by the first connecting patterns CP1. FIGS. 4 and 7A exemplarily illustrate that the second color filter G1 of the first sensing electrode IE1 and the second color filter G1 adjacent thereto of the first sensing electrode IE1 are electrically connected by the first connecting patterns CP1. The first connecting patters CP1 may be disposed on the same layer as color filters R1, G1, and B1 of the first sensing electrode IE1. However, an embodiment of the inventive concept is not limited thereto.

At least one color filter of the second sensing electrode IE2 and at least one color filter adjacent thereto of the second sensing electrode IE2 are electrically connected by the conductive patterns CCP. FIGS. 7A and 7B exemplarily illustrate that the second color filter G2 of the second sensing electrode IE2 and the second color filter G2 adjacent thereto of the second sensing electrode IE2 are electrically connected by the conductive patterns CCP. The conductive patterns CCP may be connected to the second color filter G2 through the contact holes CNT penetrating the base layer I-BS.

FIG. 7A illustrates a structure in which two second sensing electrodes IE2 adjacent to each other are connected by two conductive patterns CCP, but an embodiment of the inventive concept is not limited thereto. That is, the second sensing electrode IE2 may be connected by one conductive pattern CCP. In a structure including two conductive patterns CCP, each conductive pattern CCP may have the same structure.

The first connecting patterns CP1 and the conductive patterns CCP may overlap the light-blocking pattern BM. For example, the first connecting patterns CP1 and the conductive patterns CCP may overlap the light-blocking pattern BM on a plane. Accordingly, forming the first connecting pattern CP1 and the conductive pattern CCP may prevent the aperture ratio of a display module DM from decreasing.

According to the inventive concept, the first and second sensing electrodes IE1 and IE2 are formed of color filters CCF1, CCF2, and CCF3 through metal patterns having conductivity, thereby reducing the overall thickness of the display module DM. In addition, as the first and second sensing electrodes IE1 and IE2 may be formed overlapping pixel regions PX-R, PX-G, and PX-B, formation regions for the first and second sensing electrodes IE1 and IE2 may be widely secured. Accordingly, when the input-sensing unit CF-ISP senses an external input, sensing sensibility may be improved. In addition, the color filters CCF1, CCF2, and CCF3 formed through metal patterns having conductivity are used as the first and second sensing electrodes IE1 and IE2, so that the number of masks used for forming the input-sensing unit CF-ISP may be reduced, and as a result, a manufacturing process of the display module DM may be simplified.

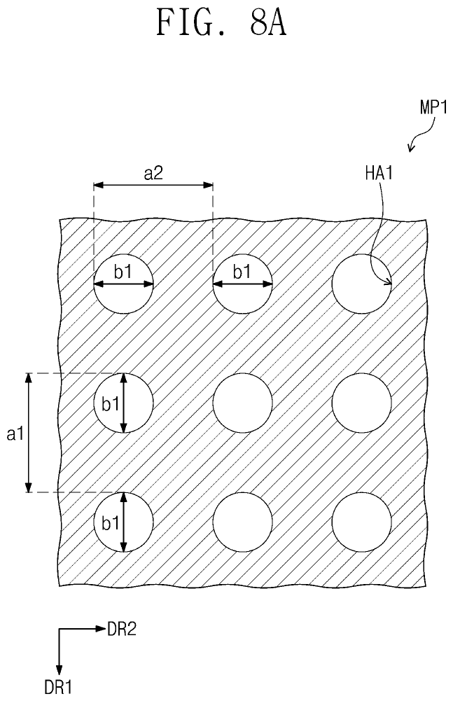

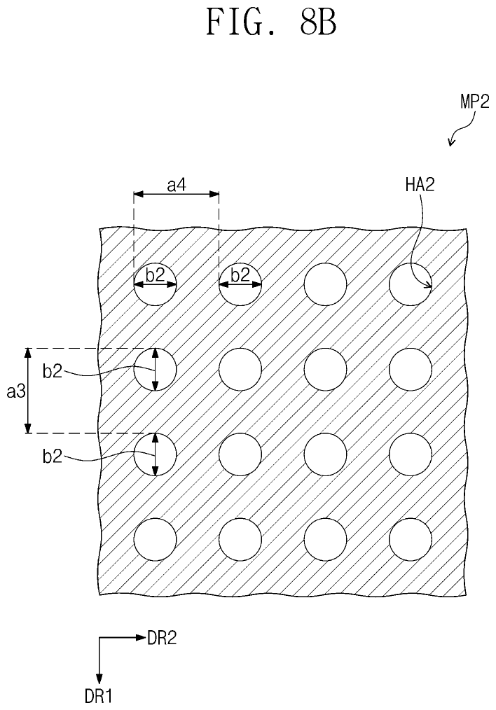

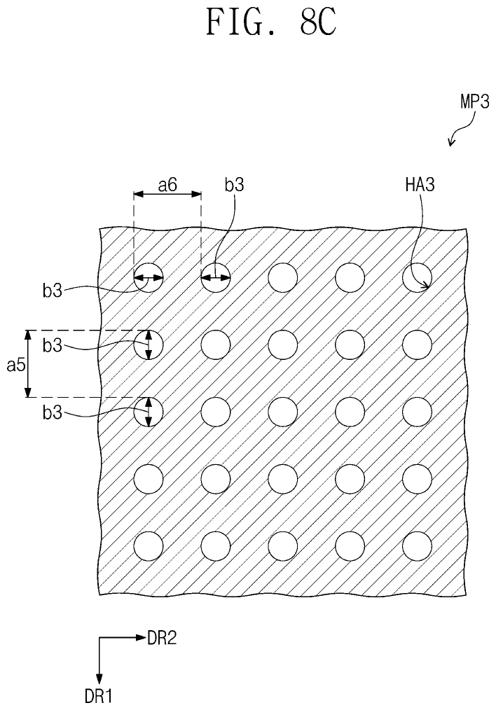

FIGS. 8A to 8C are enlarged plan views of a portion of an input-sensing unit according to another embodiment of the inventive concept. FIGS. 8A to 8C are enlarged plan views of portions of metal patterns MP1, MP2, and MP3 illustrated in FIG. 6A. Hereinafter, in describing the arrangement of input sensing units according to an embodiment of the inventive concept with reference to FIGS. 8A to 8C, like reference numerals or symbols are given to like components as those described above, and detailed descriptions thereof will be omitted.

Referring to FIGS. 5A, 5B, and 8A to 8C, an input-sensing unit CF-ISP may include a plurality of metal patterns MP1, MP2, and MP3 that transmit light of a specific wavelength. A plurality of holes HAL HA2, and HA3 arranged to have a predetermined period may be respectively defined in the plurality of metal patterns MP1, MP2, and MP3. The width (that is, diameter), or arrangement period of the plurality of holes HAL HA2, and HA3 respectively defined in the plurality of metal patterns MP1, MP2, and MP3 may be appropriately changed, thereby controlling the wavelength, full width of half maximum, transmittance, etc., of transmitted light.

The plurality of metal patterns MP1, MP2, and MP3 may include a first metal pattern MP1 respectively overlapping a plurality of first pixel regions PX-R, a second metal pattern MP2 respectively overlapping a plurality of second pixel regions PX-G, and a third metal pattern MP3 respectively overlapping a plurality of third pixel regions PX-B.

A plurality of holes HAL HA2, and HA3 having different widths may be respectively defined in the first to third metal patterns MP1, MP2, and MP3, and the plurality of holes HAL HA2, and HA3 may include a plurality of holes HA′ defined in the first metal pattern MP1, a plurality of holes HA2 defined in the second metal pattern MP2, and a plurality of holes HA3 defined in the third metal pattern MP3.

The plurality of holes HAL HA2, and HA3 respectively defined in the first to third metal patterns MP1, MP2, and MP3 may be different in planar width from each other. In an embodiment, the plurality of first holes HA1 each defined in the first metal pattern MP1, the plurality of second holes HA2 each defined in the second metal pattern MP2, and the plurality of third holes HA3 each defined in the third metal pattern MP3 may be different in planar width from each other. The plurality of first holes HA1 may have a first width on a plane, the plurality of second holes HA2 may have a second width on a plane, and the plurality of third holes HA3 may have a third width on a plane. The first width may be greater than the second width, and the third width. The second width may be greater than the third width. In an embodiment, the first width may be about 540 nm to about 640 nm, the second width may be about 450 nm to about 550 nm, and the third width may be about 350 nm to 450 nm. For example, the first width may be about 590 nm, the second width may be about 500 nm, and the third width may be about 400 nm. However, an embodiment of the inventive concept is not limited thereto. The widths of the plurality of holes HA1, HA2, and HA3 respectively defined in the first to third metal patterns MP1, MP2, and MP3 may be variously changed according to the wavelength range of transmitted light and the dielectric constants of the metal patterns MP1, MP2, and MP3.

In an embodiment, the plurality of first holes HA′ defined in the first metal pattern MP1 overlapping the plurality of first pixel regions PX-R, the plurality of second holes HA2 defined in the second metal pattern MP2 overlapping the plurality of second pixel regions PX-G, and the plurality of third holes HA3 defined in the third metal pattern MP3 overlapping the plurality of third pixel regions PX-B may be different in planar width from each other, thereby having a different arrangement on a plane.

At least a portion of the plurality of holes HA1, HA2, and HA3 respectively defined in the first metal pattern MP1, the second metal pattern MP2, and the third metal pattern MP3 may have a different arrangement period. In an embodiment, the plurality of first holes HA1 defined in the first metal pattern MP1 respectively overlapping the plurality of first pixel regions PX-R, the plurality of second holes HA2 defined in the second metal pattern MP2 respectively overlapping the plurality of second pixel regions PX-G, and the plurality of third holes HA3 defined in the third metal pattern MP3 respectively overlapping the plurality of third pixel regions PX-B may respectively have different arrangement periods. The plurality of first holes HA1 may be each arranged in a first period and spaced apart from each other on a plane, the plurality of second holes HA2 may be each arranged in a second period and spaced apart from each other on a plane, and the plurality of third holes HA3 may be arranged in a third period and spaced apart from each other on a plane. The first period may be greater than the second period and the third period, and the second period may be greater than the third period.

In an embodiment, the plurality of first holes HA′ defined in the first metal pattern MP1 overlapping the plurality of first pixel regions PX-R, the plurality of second holes HA2 defined in the second metal pattern MP2 overlapping the plurality of second pixel regions PX-G, and the plurality of third holes HA3 defined in the third metal pattern MP3 overlapping the plurality of third pixel regions PX-B may have periods different from each other, and thus have different arrangements on a plane.

Referring to FIG. 8A, the plurality of first holes HA′ defined in the first metal pattern MP1 may be arranged in a predetermined period. The plurality of first holes HA1 may be arranged in a first arrangement period a1 in the first direction DR1, and may be arranged in a second arrangement period a2 in the second direction DR2. The first arrangement period a1 and the second arrangement period a2 may be the same. However, an embodiment of the inventive concept is not limited thereto, and the first arrangement period a1 and the second arrangement period a2 may have different values.

Referring to FIG. 8B, the plurality of second holes HA2 defined in the second metal pattern MP2 may be arranged in a predetermined period. The plurality of second holes HA2 may be arranged in a third arrangement period a3 in the first direction DR1, and may be arranged in a fourth arrangement period a4 in the second direction DR2. The third arrangement period a3 and the fourth arrangement period a4 may be the same. However, an embodiment of the inventive concept is not limited thereto, and the third arrangement period a3 and the fourth arrangement period a4 may have different values.

Referring to FIG. 8C, the plurality of first holes HA3 defined in the third metal pattern MP3 may be arranged in a predetermined period. The plurality of third holes HA3 may be arranged in a fifth arrangement period a5 in the first direction DR1, and may be arranged in a sixth arrangement period a6 in the second direction DR2. The fifth arrangement period a5 and the sixth arrangement period a6 may be the same. However, an embodiment of the inventive concept is not limited thereto, and the fifth arrangement period a5 and the sixth arrangement period a6 may have different values.

As shown in FIGS. 8A to 8C, the plurality of first holes HA′ may each have a predetermined width b1, the plurality of second holes HA2 may each have a predetermined width b2, and the plurality of third holes HA3 may each have a predetermined width b3. That is, the plurality of first to third holes HA1, HA2, and HA3 may each have a circular shape on a plane. However, the shapes of the plurality of first holes to third holes HA1, HA2, and HA3 are not limited thereto. For example, the plurality of first to third holes HA1, HA2, and HA3 may have any one shape of an ellipsoid, a polygon, a stripe, etc. Meanwhile, FIGS. 8A to 8C illustrate that the first to third metal patterns MP1, MP2, and MP3 have a square hole array, but an embodiment of the inventive concept is not limited thereto. The plurality of first to third holes HA1, HA2, and HA3 respectively defined in the first to third metal patterns MP1, MP2, and MP3 may have various arrangement forms. For example, the first to third metal patterns MP1, MP2, and MP3 may have a hexagonal hole array form.

An input-sensing unit according to an embodiment of the inventive concept includes color filters including metal patterns in which holes having various periods and sizes are defined, and an oxide layer having conductivity is disposed on the metal patterns, thereby performing a function as an input sensor as well as a function as a color filter that transmits light of a specific wavelength range. In particular, a sensing electrode may be formed using a color filter capable of functioning as an input sensor, thereby reducing the overall thickness and tact time for a display device. In addition, since it is possible to make the sensing electrode become wide in the light-emitting regions, the sensing sensitivity in sensing an external input may be improved, thereby further improving the reliability of a display device.

According to the inventive concept, since an input-sensing unit capable of sensing an external input while having an antireflection function is provided, the overall sensing sensitivity of a display device may be improved, and the overall thickness of the display device may be reduced.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a display panel including a plurality of pixel regions; and
an input-sensing unit including an inorganic material-containing optical layer disposed on the display panel, and a plurality of metal patterns disposed on the optical layer and respectively corresponding to the plurality of pixel regions,
wherein the plurality of pixel regions include a first pixel region and a second pixel region, and
the plurality of metal patterns include a first metal pattern overlapping the first pixel region and transmitting first light, and a second metal pattern overlapping the second pixel region and transmitting second light having a wavelength different from that of the first light.

2. The display device of claim 1, wherein the first metal pattern includes a plurality of holes, and
the second metal pattern includes a plurality of second holes having a planar arrangement different from that of the plurality of first holes.

3. The display device of claim 2, wherein the input-sensing unit further comprises:
a first oxide layer disposed on the first metal pattern; and
a second oxide layer disposed on the second metal pattern.

4. The display device of claim 3, wherein the first oxide layer and the second oxide layer each comprise a transparent conductive oxide.

5. The display device of claim 3, wherein the first oxide layer is disposed filling the plurality of first holes, and
the second oxide layer is disposed filling the plurality of second holes.

6. The display device of claim 2, wherein the plurality of first holes each have a first width, and
the plurality of second holes each have a second width different from the first width.

7. The display device of claim 2, wherein the plurality of first holes are arranged with a first period, and
the plurality of second holes are arranged with a second period different from the first period.

8. The display device of claim 2, wherein the plurality of first holes penetrate through the first metal pattern, and
the plurality of second holes penetrate through the second metal pattern.

9. The display device of claim 1, wherein the optical layer comprises a plurality of inorganic films having refractive indices different from each other.

10. The display device of claim 1, wherein the optical layer comprises:
at least one first inorganic film having a first refractive index; and
at least one second inorganic film having a second refractive index different from the first refractive index,
the at least one first inorganic film and the at least one second inorganic film being alternately stacked.

11. The display device of claim 1, wherein the input-sensing unit further comprises a light-blocking pattern disposed between the plurality of metal patterns.

12. The display device of claim 1, wherein the display panel further comprises an encapsulation layer configured to cover the plurality of pixel regions, and the input-sensing unit is directly disposed on the encapsulation layer.

13. A display device comprising:
a display panel including a plurality of first pixel regions configured to generate first light, and a plurality of second pixel regions configured to generate second light having a wavelength different from that of the first light; and
an input-sensing unit disposed on the display panel, and including a first color filter overlapping the plurality of first pixel regions and a second color filter overlapping the plurality of second pixel regions,
wherein the first color filter includes a first metal pattern that includes a plurality of first holes,
a first oxide layer configured to fill the plurality of first holes and disposed on the first metal pattern,
the second color filter includes a second metal pattern that includes a plurality of second holes having a planar arrangement different from that of the plurality of first holes, and
a second oxide layer configured to fill the plurality of second holes and disposed on the second metal pattern.

14. The display device of claim 13, wherein the input-sensing unit further comprises an optical layer disposed between the display panel and the first and second color filters, and
the optical layer has a multi-layered structure in which a plurality of inorganic films having different refractive indices are alternately stacked.

15. The display device of claim 13, wherein the plurality of first holes are arranged with a first period, and
the plurality of second holes are arranged with a second period different from the first period.

16. The display device of claim 13, wherein the plurality of first holes are penetrate through the first metal pattern, and
the plurality of second holes penetrate through the second metal pattern.

17. The display device of claim 13, wherein the first oxide layer and the second oxide layer each comprise a transparent conductive oxide.

18. The display device of claim 13, wherein the first light is red light, and the second light is green light.

19. The display device of claim 13, wherein
the display panel further comprises a plurality of third pixel regions configured to generate third light having a wavelength different from those of the first light and the second light,
the input-sensing unit further comprises a third color filter disposed on the display panel, and overlapping the plurality of third pixel regions, and
the third color filter comprises a third metal pattern that includes a plurality of third holes, and
a third oxide layer configured to fill the plurality of third holes.

20. The display device of claim 19, wherein
the plurality of first holes each have a first width,
the plurality of second holes each have a second width different from the first width,
the plurality of third holes each have a third width different from the first width and the second width, and
the first width being about 540 nm to about 640 nm, the second width being about 450 nm to about 550 nm, and the third width being about 350 nm to about 450 nm.
